(19) United States
(12) Patent Application Publication
(10) Pub. No.: US 2025/0151485 A1
(43) Pub. Date: May 8, 2025

(54) LIGHT-EMITTING MODULE

(71) Applicant: NICHIA CORPORATION, Anan-shi (JP)

(72) Inventor: Norimasa YOSHIDA, Komatsushima-shi (JP)

(73) Assignee: NICHIA CORPORATION, Anan-shi (JP)

(21) Appl. No.: 18/932,183

(22) Filed: Oct. 30, 2024

(30) Foreign Application Priority Data
Nov. 6, 2023 (JP) 2023-189653

(51) Int. Cl. H01L 33/58; H01L 25/075

(52) U.S. Cl. CPC H10H 20/855; H01L 25/0753

(57) ABSTRACT

A light-emitting module includes: a first light source; and a second light source disposed separated from the first light source in a top view. The first light source includes: a plurality of light-emitting parts including a first light-emitting part and a plurality of second light-emitting parts arranged around the first light-emitting part, and a light-shielding member disposed between the plurality of light-emitting parts such that light-emitting surfaces of the plurality of respective light-emitting parts are exposed from the light-shielding member. The second light source comprises a third light-emitting part electrically connected in parallel with the first light-emitting part. Light emitted from the first light-emitting part and light emitted from the third light-emitting part at least partially overlap each other on an irradiation surface.

### CROSS-REFERENCE TO RELATED APPLICATIONS

This application is based on and claims priority to Japanese Patent Application No. 2023-189653, filed on Nov. 6, 2023, the entire contents of which are incorporated herein by reference.

### TECHNICAL FIELD

The present disclosure relates to a light-emitting module.

### BACKGROUND

Light-emitting modules including semiconductor elements such as light-emitting diodes (LEDs) have been widely used. For example, Japanese Patent Publication No. 2023-017456 describes a light-emitting device that combines and emits light beams from a plurality of light sources disposed separated from each other.

### SUMMARY

An object of the present disclosure is to provide a light-emitting module that can emit light having desired characteristics.

A light-emitting module according to one embodiment of the present disclosure includes a first light source; and a second light source disposed separated from the first light source in an in-plane direction, wherein the first light source includes a plurality of light-emitting parts, the plurality of light-emitting parts including a first light-emitting part and a plurality of second light-emitting parts arranged around the first light-emitting part, and a light-shielding member disposed between the plurality of light-emitting parts and exposing light-emitting surfaces of the plurality of respective light-emitting parts, the second light source includes a third light-emitting part connected in parallel with the first light-emitting part, and light emitted from the first light-emitting part and light emitted from the third light-emitting part at least partially overlap each other on an irradiation surface.

A light-emitting module according to one embodiment of the present disclosure includes a first light source including a first light-emitting part and a plurality of second light-emitting parts arranged around the first light-emitting part; and a second light source disposed separated from the first light source in an in-plane direction and including a third light-emitting part, wherein light from the first light-emitting part and light from the third light-emitting part at least partially overlap each other on an irradiation surface, a first irradiation mode in which the first light-emitting part and the third light-emitting part emit light and a second irradiation mode in which each of the first light-emitting part, the plurality of second light-emitting parts, and the third light-emitting part emits light are switchable, and a light distribution angle in the first irradiation mode is smaller than a light distribution angle in the second irradiation mode.

### BRIEF DESCRIPTION OF THE DRAWINGS

FIG. 1 is a schematic top view of a light-emitting module according to an embodiment;

FIG. 2 is a schematic cross-sectional view taken through line II-II of FIG. 1;

FIG. 3 is a schematic top view illustrating a first light source and a second light source of the light-emitting module according to the embodiment;

FIG. 4 is a schematic diagram illustrating light emitted from a first light-emitting part onto an irradiation surface and light emitted from a third light-emitting part onto the irradiation surface in the light-emitting module according to the embodiment;

FIG. 5 is a schematic cross-sectional view taken through line V-V of FIG. 3;

FIG. 6 is a schematic cross-sectional view illustrating a first example of a first light source of the light-emitting module according to the embodiment;

FIG. 7 is a schematic cross-sectional view illustrating a second example of a first light source of the light-emitting module according to the embodiment;

FIG. 8 is a schematic top view of a first lens of the light-emitting module according to the embodiment;

FIG. 9 is a schematic bottom view of the first lens of the light-emitting module according to the embodiment;

FIG. 10 is a schematic cross-sectional view taken through line X-X of FIG. 8;

FIG. 11 is a schematic cross-sectional view illustrating a second lens according to a first modification, which is included in the light-emitting module according to the embodiment;

FIG. 12 is a schematic cross-sectional view illustrating a second lens according to a second modification, which is included in the light-emitting module according to the embodiment;

FIG. 13 is a schematic cross-sectional view illustrating a second lens according to a third modification, which is included in the light-emitting module according to the embodiment;

FIG. 14 is a schematic cross-sectional view illustrating a second lens according to a fourth modification, which is included in the light-emitting module according to the embodiment;

FIG. 15 is a schematic cross-sectional view of a light-emitting module according to a first modification;

FIG. 16 is a schematic cross-sectional view of a light-emitting module according to a second modification;

FIG. 17 is a schematic top view illustrating a first example of a second light source of the light-emitting module according to the second modification;

FIG. 18 is a schematic top view illustrating a second example of a second light source of the light-emitting module according to the second modification; and

FIG. 19 is a schematic cross-sectional view of a light-emitting module according to a third modification.

### DETAILED DESCRIPTION

A light-emitting module according to an embodiment of the present disclosure will be described in detail with reference to the accompanying drawings. The embodiment described below exemplifies the light emitting module to embody the technical ideas behind the invention, but the invention is not limited to the described embodiment. In addition, unless otherwise specified, the dimensions, materials, shapes, relative arrangements, and the like of components described in the embodiment are not intended to limit the scope of the present disclosure thereto, but are described as examples. The sizes, positional relationships, and the like of members illustrated in the drawings may be exaggerated for clearer illustration. Further, in the following description, the same names and reference numerals refer to the same or similar members, and a detailed description thereof will be omitted as appropriate. An end view illustrating only a cut surface may be used as a cross-sectional view.

In the drawings, directions may be indicated by an X-axis, a Y-axis, and a Z-axis. The X-axis, the Y-axis, and the Z-axis are orthogonal to one another. An X direction along the X-axis and a Y direction along the Y-axis indicate directions along a light-emitting surface of a light-emitting part of the light-emitting module according to the embodiment. A Z direction along the Z-axis indicates a direction orthogonal to the light-emitting surface. That is, the light-emitting surface of the light-emitting part is parallel to the XY plane, and the Z-axis is orthogonal to the XY plane.

A direction indicated by an arrow in the X direction is referred to as a +X side, and a direction opposite to the +X side is referred to as a −X side. A direction indicated by an arrow in the Y direction is referred to as a +Y side, and a direction opposite to the +Y side is referred to as a −Y side. A direction indicated by an arrow in the Z direction is referred to as a +Z side, and a direction opposite to the +Z side is referred to as a −Z side. In the embodiment, a first light source and a second light source of the light-emitting module are configured to emit light to the +Z side as an example. Further, the phrase “in a top view” as used in the embodiment refers to viewing an object from above. As an example, the phrase “in a top view” as used in the embodiment refers to viewing an object from the upper surface side of a first lens of the light-emitting module according to the embodiment. However, these expressions do not limit the orientation of the light-emitting module according to the embodiment during use, and the orientation of the light-emitting module according to the embodiment is discretionary. In the present specification, the phrase “in a top view” may be used to describe, in addition to a portion that can be directly seen from above, a portion that cannot be directly seen from above as if it can be seen from above.

Further, in the present specification, a surface of an object as viewed from the +Z side is referred to as an “upper surface,” and a surface of the object as viewed from the −Z side is referred to as a “lower surface.” In the embodiment described below, each of “along the X-axis,” “along the Y-axis,” and “along the Z-axis” includes a case where the object is at an inclination within a range of +10° with respect to the corresponding one of the axes. Further, in the embodiment, the term “parallel” may include a deviation within +10° with respect to 0°. Further, in the embodiment, the term “orthogonal” may include a deviation within +10° with respect to 90°.

### Embodiment

### <Example Configuration of Light-Emitting Module According to Embodiment>

### (Overall Configuration)

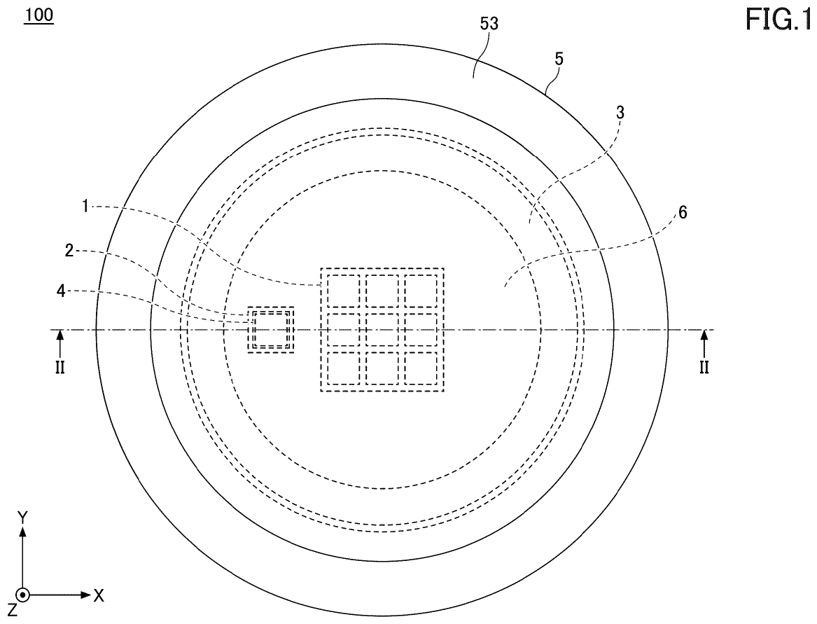

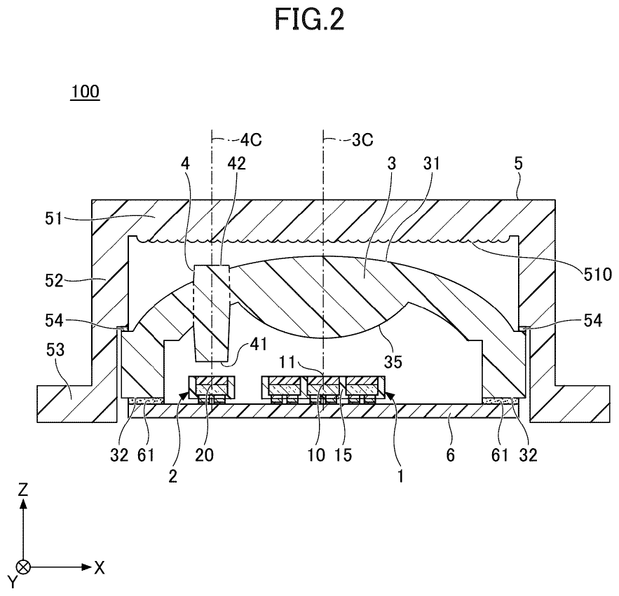

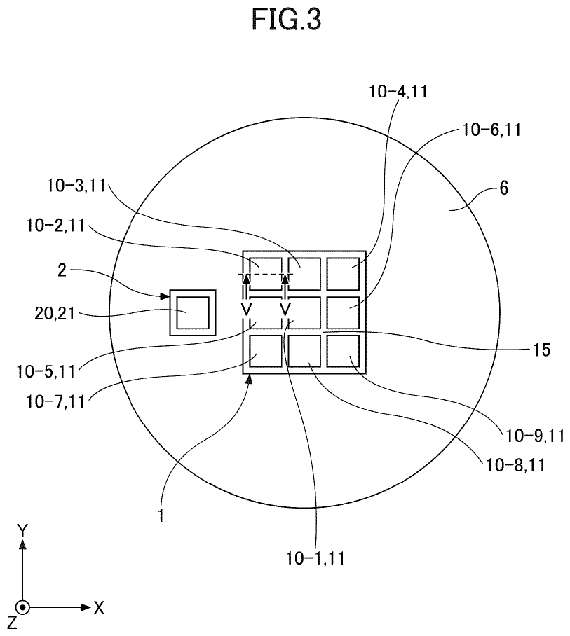

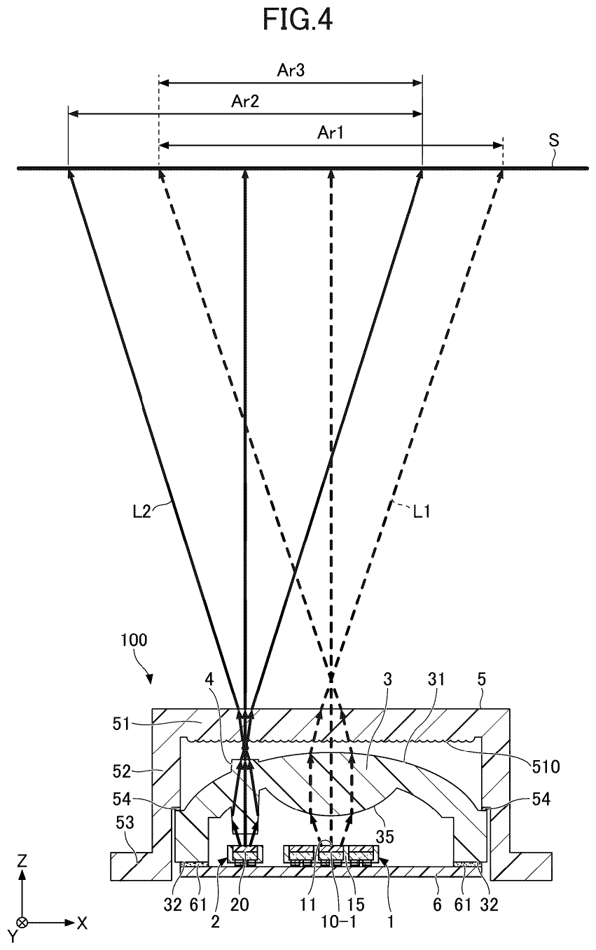

The overall configuration of a light-emitting module according to an embodiment will be described with reference to FIG. 1 to FIG. 4. FIG. 1 is a schematic top view illustrating an example of a light-emitting module 100 according to an embodiment. FIG. 2 is a schematic cross-sectional view taken through line II-II of FIG. 1. FIG. 3 is a schematic top view illustrating a first light source 1 and a second light source 2 of the light-emitting module 100. FIG. 3 illustrates the light-emitting module 100 from which a first lens 3, a second lens 4, and a light-transmissive member 5 are removed. FIG. 4 is a schematic diagram illustrating light L1 emitted from a first light-emitting part 10-1 onto an irradiation surface S and light L2 emitted from a third light-emitting part 20 onto the irradiation surface S in the light-emitting module 100.

As illustrated in FIG. 1 to FIG. 4, the light-emitting module 100 includes the first light source 1 and the second light source 2 disposed separated from the first light source 1 in the in-plane direction. The in-plane direction is a direction along a light-emitting surface 11 of a light-emitting part 10 of the first light source 1, and in the example illustrated in FIG. 1 to FIG. 4, the in-plane direction is a direction along the XY plane. The first light source 1 includes a plurality of light-emitting parts 10 and a light-shielding member 15 disposed between the plurality of light-emitting parts 10. Light-emitting surfaces 11 of the plurality of respective light-emitting parts 10 are exposed from the light-shielding member 15. The plurality of light-emitting parts 10 include a first light-emitting part 10-1 and a plurality of second light-emitting parts 10-2 to 10-9 arranged around the first light-emitting part 10-1. The second light source 2 includes the third light-emitting part 20 electrically connected in parallel with the first light-emitting part 10-1. The light L1 from the first light-emitting part 10-1 and the light L2 from the third light-emitting part 20 at least partially overlap each other on the irradiation surface S.

In the example illustrated in FIG. 4, a first irradiation region Ar1 represents a region in the irradiation surface S irradiated with the light L1 from the first light-emitting part 10-1. A second irradiation region Ar2 represents a region in the irradiation surface S irradiated with the light L2 from the third light-emitting part 20. A third irradiation region Ar3 represents a region in the irradiation surface S where the light L1 and the light L2 overlap each other. In the third irradiation region Ar3, because the light L1 and the light L2 overlap each other, the amount of light increases. Accordingly, bright irradiation light is obtained in the third irradiation region Ar3.

As an example, the light-emitting module 100 is a light-emitting module installed in a smartphone and used for a flash of an imaging device provided in the smartphone. The imaging device includes a camera for capturing a still image, a video camera for capturing a moving image, and the like.

In the example illustrated in FIG. 1 to FIG. 4, the first light source 1 includes nine light-emitting parts 10 arranged in a 3×3 matrix. The first light-emitting part 10-1 is positioned at the center. The second light-emitting parts 10-2 to 10-9 are positioned around the first light-emitting part 10-1. The light-emitting module 100 can select light-emitting part(s) 10 to emit light, from among the nine light-emitting parts 10 included in the first light source 1, according to a photographing mode such as a telephoto photography mode or a wide-angle photography mode of the imaging device installed in the smartphone, for example. The light-emitting module 100 can emit irradiation light corresponding to each irradiation mode by selecting light-emitting part(s) 10 to emit light and allowing the selected light-emitting part(s) 10 to emit light through a lens.

For example, in telephoto photography, the light-emitting module 100 can set an irradiation mode to a telephoto irradiation mode by allowing only the first light-emitting part 10-1 to emit light and allowing the second light-emitting parts 10-2 to 10-9 not to emit light. The telephoto irradiation mode makes the light distribution angle of irradiation light narrower, thereby allowing the light to reach a long distance. The imaging device can perform telephoto photography by using irradiation light in the telephoto irradiation mode.

In the wide-angle photography, the light-emitting module 100 allows the second light-emitting part 10-3, the second light-emitting part 10-8, the second light-emitting part 10-5, and the second light-emitting part 10-6 adjacent to the first light-emitting part 10-1 in the vertical direction and the lateral direction among the nine light-emitting parts 10 to emit a first amount of light. In addition, the light-emitting module 100 allows the second light-emitting part 10-2, the second light-emitting part 10-4, the second light-emitting part 10-7, and the second light-emitting part 10-9 adjacent to the first light-emitting part 10-1 in the diagonal direction to emit a second amount of light. The second amount of light is larger than the first amount of light. In addition, the light-emitting module 100 allows the first light-emitting part 10-1 to emit a third amount of light. The third amount of light is smaller than the first amount of light. In this manner, the light-emitting module 100 can set the irradiation mode to a wide-angle irradiation mode. The wide-angle irradiation mode makes the light distribution angle of irradiation light wider than the light distribution angle in the telephoto photography, thereby allowing the light to be emitted in a wide range. The imaging device can perform the wide-angle photography by using irradiation light in the wide-angle irradiation mode.

For example, in the telephoto irradiation mode, a predetermined amount of light needs to be emitted only by the first light-emitting part 10-1 as described above, and thus a current applied to the first light-emitting part 10-1 is likely to increase. If a current applied to the first light-emitting part 10-1 is increased to increase the amount of light, there may be a case where a junction temperature Tj of a light-emitting element of the first light-emitting part 10-1 may exceed an allowable value. Specifically, in the light-emitting module in which a predetermined current E (for example, a current of 2.5 A) is supposed to be applied to the first light-emitting part 10-1, if a current larger than the predetermined current E (for example, a current of 3.0 A) is applied to the first light-emitting part 10-1 in order to increase the amount of light, the junction temperature Tj of the light-emitting element would increase and exceed the allowable value. Further, in order to decrease the junction temperature Tj of the light-emitting element of the first light-emitting part 10-1, if the current is divided into the second light-emitting parts 10-2 to 10-9 located around the first light-emitting part 10-1, light from the second light-emitting parts 10-2 to 10-9 would be unable to reach a long distance because the light distribution angle of the light from the second light-emitting parts 10-2 to 10-9 is wider than the light distribution angle of light from the first light-emitting part 10-1. As a result, the amount of light in the telephoto irradiation mode would be decreased, and the quality of telephoto photography by the imaging device would be degraded.

Conversely, in the light-emitting module 100, the first light-emitting part 10-1 of the first light source 1 and the third light-emitting part 20 of the second light source 2 are electrically connected in parallel, and thus a current applied to the light-emitting module 100 at the time of light emission is divided into the first light-emitting part 10-1 and the third light-emitting part 20. By dividing the input current, the first light-emitting part 10-1 and the third light-emitting part 20 can emit light in parallel. The light L1 from the first light-emitting part 10-1 and the light L2 from the third light-emitting part 20 at least partially overlap each other on the irradiation surface S. By allowing the light L1 and the light L2 to overlap each other on the irradiation surface S, the amount of the light L1 can be supplemented by the amount of the light L2. Therefore, in the telephoto irradiation mode, the amount of light on the irradiation surface S can be increased, and thus the light can be made bright. Accordingly, in the present embodiment, the light-emitting module 100 that can emit light having desired characteristics can be provided. Specifically, the light-emitting module 100 that can emit light such that desired light amount characteristics can be obtained on the irradiation surface S can be provided.

Further, in the light-emitting module 100, by dividing the current applied to the light-emitting module 100 into the first light-emitting part 10-1 and the third light-emitting part 20, a temperature rise of the first light-emitting part 10-1 due to current concentration on the first light-emitting part 10-1 can be reduced. Further, in the light-emitting module 100, the second light source 2 including the third light-emitting part 20 is disposed separated from the first light source 1 including the first light-emitting part 10-1. Accordingly, as compared to the case in which the third light-emitting part 20 and the first light-emitting part 10-1 are disposed close to each other, heat dissipation can be improved, and thus a temperature rise of the first light-emitting part 10-1 can be reduced. By reducing a temperature rise of the first light-emitting part 10-1, the temperature of the light-emitting element of the first light-emitting part 10-1 is unlikely to exceed the allowable value of the junction temperature Tj during the light emission. Thus, failures, damage, or the like to the light-emitting module 100 can be reduced. As a result, in the present embodiment, a highly reliable light-emitting module 100 can be provided.

In another aspect of the light-emitting module 100, the first light-emitting part 10-1 of the first light source 1 and the third light-emitting part 20 of the second light source 2 do not have to be connected in parallel, as long as the light L1 from the first light-emitting part 10-1 and the light L2 from the third light-emitting part 20 at least partially overlap each other on the irradiation surface S. For example, the light-emitting module 100 includes the first light source 1 including the first light-emitting part 10-1 and the second light-emitting parts 10-2 to 10-9 arranged around the first light-emitting part 10-1, and the second light source 2 disposed separated from the first light source 1 in the in-plane direction and including the third light-emitting part 20. The light L1 from the first light-emitting part 10-1 and the light L2 from the third light-emitting part 20 at least partially overlap each other on the irradiation surface S. The light-emitting module 100 can switch between a first irradiation mode in which only the first light-emitting part 10-1 and the third light-emitting part 20 emit light and a second irradiation mode in which each of the first light-emitting part 10-1, the second light-emitting parts 10-2 to 10-9, and the third light-emitting part 20 emits light. A light distribution angle in the first irradiation mode is smaller than a light distribution angle in the second irradiation mode. The first irradiation mode corresponds to, for example, the telephoto irradiation mode. The second irradiation mode corresponds to, for example, the wide-angle irradiation mode. As described above, in the first irradiation mode (for example, the telephoto irradiation mode), both the first light-emitting part 10-1 and the third light-emitting part 20 emit light. Therefore, as compared to a light-emitting module in which only a first light-emitting part 10-1 emits light in the first irradiation mode, the light-emitting module 100 according to the present embodiment can be provided with which the amount of light on the irradiation surface S can be increased, and light having desired characteristics can be emitted.

In the example illustrated in FIG. 1 to FIG. 3, the light-emitting module 100 further includes the first lens 3 disposed above the first light source 1. The first lens 3 illustrated in FIG. 2 has a first incident surface 35 on which light from the first light source 1 is incident and a first exit surface 31 from which the light from the first light source 1 exits. The first incident surface is convex toward the first light source 1. The first exit surface 31 is located opposite to the first incident surface 35. It is preferable that each of the first incident surface 35 and the first exit surface 31 overlaps the first light source 1 and does not overlap the second light source 2 in a top view. Further, the light transmissivity of the first lens 3 preferably refers to having a light transmittance of 60% or more with respect to the emission peak wavelength of the light emitted from the first light source 1. This configuration of the light-emitting module 100 can reduce light emitted from the second light source 2 to be incident on the first incident surface 35 of the first lens 3. Accordingly, the amount of stray light generated when the light from the second light source 2 is incident on the first incident surface 35 can be reduced, and thus the quality of irradiation light by the light-emitting module 100 can be improved. The improved quality of irradiation light means that, for example, the light distribution pattern of irradiation light has symmetry or light is unlikely to be emitted to an unintended region in the irradiation surface S.

Further, in the example illustrated in FIG. 1 to FIG. 3, the light-emitting module 100 further includes the second lens 4 disposed above the third light-emitting part 20 and having a second incident surface 41. The second incident surface 41 faces a third light-emitting surface 21 of the third light-emitting part 20 and is positioned separated from the first incident surface 35 in a top view. As illustrated in FIG. 1 and FIG. 2, a rod-shaped light-transmissive member having a substantially rectangular shape in a top view and elongated in the Z direction can be used as the second lens 4. The light transmissivity of the second lens 4 preferably refers to having a light transmittance of 60% or more with respect to the emission peak wavelength of the light L2 emitted from the third light-emitting part 20.

The light L2 emitted from the third light-emitting part 20 enters to the inside of the second lens 4 through the second incident surface 41 of the second lens 4. The second lens 4 can guide the light L2 having entered to the inside through the second incident surface 41 in the +Z direction, and allow the light L2 to exit from a second exit surface 42. Further, the second incident surface 41 of the second lens 4 and the third light-emitting surface 21 of the third light-emitting part 20 preferably have the substantially same shape in a top view. For example, each of the second incident surface 41 of the second lens 4 and the third light-emitting surface 21 of the third light-emitting part 20 has a substantially rectangular shape. Further, the shape of the second incident surface 41 of the second lens 4 and the shape of the third light-emitting surface 21 of the third light-emitting part 20 may be similar to each other or may be congruent with each other. When the second incident surface 41 of the second lens 4 and the third light-emitting surface 21 of the third light-emitting part 20 have substantially the same shape in a top view, loss of light due to the light L2 from the third light-emitting part 20 not being incident on the second lens 4 tends to be reduced, as compared to the case in which the second incident surface 41 of the second lens 4 and the third light-emitting surface 21 of the third light-emitting part 20 have different shapes in a top view. Accordingly, the light extraction efficiency of the light-emitting module 100 can be increased. The second incident surface 41 of the second lens 4 and the third light-emitting surface 21 of the third light-emitting part 20 may have different shapes from each other in a top view.

The light-emitting module 100 includes the second lens 4 configured to guide the light L2 emitted from the third light-emitting part 20, and thus the light L2 emitted from the third light-emitting part 20 is less likely to be incident on the first incident surface 35 of the first lens 3. Accordingly, the amount of stray light generated when the light L2 from the third light-emitting part 20 is incident on the first incident surface 35 can be reduced. In addition, including the second lens 4 in the light-emitting module 100 can improve the extraction efficiency of the light L2 emitted from the third light-emitting part 20, and can increase the amount of light on the irradiation surface S.

Further, in the example illustrated in FIG. 1 to FIG. 3, a first optical axis 3C of the first lens 3 passing through the center of the first incident surface 35 intersects the first light-emitting part 10-1, and a second optical axis 4C of the second lens 4 passing through the center of second incident surface 41 intersects the third light-emitting part 20. The second optical axis 4C is parallel to the first optical axis 3C. With this configuration, light from the first light-emitting part 10-1 and light from the third light-emitting part 20 are emitted in the same direction, and thus the light from the first light-emitting part 10-1 and the light from the third light-emitting part 20 easily overlap each other on the irradiation surface S. Therefore, the amount of light from the first light-emitting part 10-1 can be easily supplemented by the amount of light from the third light-emitting part 20. Accordingly, the light-emitting module 100 can increase the amount of light in the first irradiation mode (for example, the telephoto irradiation mode).

Further, in the example illustrated in FIG. 1 to FIG. 3, the second lens 4 has the second exit surface 42 from which the light L2 emitted from the third light-emitting part 20 and incident on the second incident surface 41 exits. The second incident surface 41 and the second exit surface 42 are preferably flat surfaces parallel to each other. When the second incident surface 41 and the second exit surface 42 are flat surfaces parallel to each other, after the light L2 from the third light-emitting part 20 is transmitted through the second lens 4, unevenness in the illuminance distribution of the light L2 from the third light-emitting part 20 can be reduced, and the light L2 from the third light-emitting part 20 can be controlled by the second lens 4 with higher accuracy. The second exit surface 42 may have any of a plurality of recesses and projections, a convex surface, or a concave surface. The plurality of recesses and projections include either a plurality of recesses or a plurality of projections, or include both a plurality of recesses and a plurality of projections. The plurality of recesses and projections may be formed in a concentric Fresnel shape. When the second exit surface 42 has any of the plurality of recesses and projections, the convex surface, or the concave surface, the second lens 4 can control the light L2 from the third light-emitting part 20 with higher accuracy.

Further, in the example illustrated in FIG. 1 to FIG. 3, the second incident surface 41 is located at a position lower than the first incident surface 35, and the second exit surface 42 is located at a position higher than the first incident surface 35. This configuration can reduce the light L2 emitted from the third light-emitting part 20 to be incident on the first incident surface 35 of the first lens 3. Specifically, the light L2 emitted from the third light-emitting part 20 is mainly incident on the second incident surface 41 of the second lens 4, and then emitted onto the irradiation surface S through the second exit surface 42. Accordingly, the amount of stray light generated when the light L2 from the third light-emitting part 20 is incident on the first incident surface 35 can be reduced.

Further, in the light-emitting module 100, a current value applied to the third light-emitting part 20 is preferably equal to or less than a current value applied to the first light-emitting part 10-1. In other words, in the light-emitting module 100, a current value applied to the first light-emitting part 10-1 is preferably equal to or greater than a current value applied to the third light-emitting part 20. Each of the first light-emitting part 10-1 and the plurality of second light-emitting parts 10-2 to 10-9 of the first light source 1 can partially irradiate a corresponding region among a plurality of divided regions within an irradiation range on the irradiation surface S with light. Conversely, the second light source 2 including the third light-emitting part 20 is disposed separated from the first light source 1 in the in-plane direction. Therefore, although light emitted from the second light source 2 at least partially overlaps the irradiation region of the first light-emitting part 10-1 on the irradiation surface S, it may be difficult to accurately irradiate a divided region within the irradiation range with the light. Therefore, by setting the current value applied to the first light-emitting part 10-1 to be equal to or greater than the current value applied to the third light-emitting part 20, the first light source 1 functions as a primary light source in the light-emitting module 100, and the second light source 2 functions as an auxiliary light source. As a result, the light-emitting module 100 can perform partial irradiation with high accuracy. Accordingly, for example, while the first light source 1 can accurately perform partial irradiation to each of the regions arranged in a matrix within the irradiation range, the second light source 2 can perform auxiliary irradiation to a center region. In the light-emitting module 100, the current value applied to the third light-emitting part 20 may be greater than the current value applied to the first light-emitting part 10-1.

Further, the light-emitting module 100 can switch between the first irradiation mode in which only the first light-emitting part 10-1 and the third light-emitting part 20 emit light and the second irradiation mode in which each of the first light-emitting part 10-1, the second light-emitting parts 10-2 to 10-9, and the third light-emitting part 20 emits light. The light distribution angle of the light-emitting module 100 in the first irradiation mode is smaller than the light distribution angle of the light-emitting module 100 in the second irradiation mode. By reducing the light distribution angle in the first irradiation mode, light emitted from the light-emitting module 100 can reach a long distance, as compared to a light-emitting module having a large light distribution angle in the first irradiation mode. Accordingly, for example, in an imaging device configured to capture an image by using light emitted from the light-emitting module 100, a sufficient amount of light is easily supplied during telephoto photography.

As described above, the light-emitting module 100 can be used as a flash light source. When the light-emitting module 100 is used as a flash light source, in the first irradiation mode in particular, the temperature of the first light-emitting part 10-1 exceeding the allowable value of the junction temperature Tj can be suppressed at the time of light emission. Accordingly, in the present embodiment, a highly reliable light-emitting module 100, used for a flash and capable of suppressing failures, damage, or the like due to the temperature of the light-emitting part 10 exceeding the allowable value of the junction temperature Tj in a specific irradiation mode, can be provided.

Further, in the light-emitting module 100, the planar size of a light-emitting element included in the third light-emitting part 20 may be larger than the planar size of a light-emitting element included in the first light-emitting part 10-1. By making the planar size of the light-emitting element included in the third light-emitting part 20 larger than the planar size of the light-emitting element included in the first light-emitting part 10-1, a heat or electrical resistance value of the third light-emitting part 20 is reduced. Accordingly, heat accumulation in the third light-emitting part 20 can be reduced, and failures, damage, or the like to the third light-emitting part 20 can be suppressed. Further, by increasing the planar size of the light-emitting element included in the third light-emitting part 20, the size of an electrode of the third light-emitting part 20 or the size of corresponding wiring of a substrate tends to increase, thereby allowing heat generated by the third light-emitting part 20 to be efficiently dissipated.

In the light-emitting module 100, the planar size of the light-emitting element included in the third light-emitting part 20 may be smaller than the planar size of the light-emitting element included in the first light-emitting part 10-1. By making the light-emitting element included in the third light-emitting part 20 smaller than the light-emitting element included in the first light-emitting part 10-1, the third light-emitting part 20 can be made close to a point light source, and thus the light distribution of the third light-emitting part 20 can be easily controlled.

In the light-emitting module 100, the distance between the first light-emitting part 10-1 and the third light-emitting part 20 is, for example, 500 μm or more and 2, 500 μm or less, and preferably 1,000 μm or more and 2,000 μm or less. The distance between the first light-emitting part 10-1 and the third light-emitting part 20 is, for example, the shortest distance between a light-emitting element included in the first light-emitting part 10-1 and a light-emitting element included in the third light-emitting part 20 in a top view. Further, the distance between the first light-emitting part 10-1 and the third light-emitting part 20 is, for example, 5 times or more and 30 times or less, and preferably 10 times or more and 20 times or less the distance between the first light-emitting part 10-1 and each of the second light-emitting parts 10-3, 10-5, 10-6, and 10-8 adjacent to the first light-emitting part 10-1 in the X direction or the Y direction. For example, the distance between the first light-emitting part 10-1 and the second light-emitting part 10-3 is the shortest distance between one of the light-emitting elements included in the first light-emitting part 10-1 and a light-emitting element included in the second light-emitting part 10-3 in a top view. Further, the distance from each of a light-emitting surface 11 of the first light-emitting part 10-1 and the third light-emitting surface 21 of the third light-emitting part 20 to the irradiation surface S is, for example, 0.01 m or more and 10 m or less, and preferably 0.10 m or more and 5 m or less. The illuminance in the third irradiation region Ar3 on the irradiation surface S is 100 lux or more and preferably 1,000 lux or more when the distance from the third light-emitting surface 21 of the third light-emitting part 20 to the irradiation surface S is 0.3 mm, for example.

### (Detailed Configuration)

Each component of the light-emitting module 100 will be described in detail below.

### (Light-Transmissive Member 5)

As illustrated in FIG. 1 to FIG. 3, the light-emitting module 100 can include the light-transmissive member 5. The light-transmissive member 5 includes an upper portion 51 facing the first exit surface 31 of the first lens 3, a cylindrical portion 52 supporting an end portion of the upper portion 51, and a leg portion 53 disposed in contact with a lower portion of the cylindrical portion 52. In the light-transmissive member 5 illustrated in FIG. 2, the upper portion 51, the cylindrical portion 52, and the leg portion 53 are a monolithic member. However, the upper portion 51, the cylindrical portion 52, and the leg portion 53 may be separate members that are not connected to each other. The light-transmissive member 5 is disposed so as to cover the first light source 1, the second light source 2, the first lens 3, and the second lens 4. The light-transmissive member 5 is bonded to the first lens 3 by a first bonding member 54 disposed annularly on an outer edge portion of the first lens 3 in a top view. In the example illustrated in FIG. 1, the light-transmissive member 5 has a substantially circular shape in a top view. However, the light-transmissive member 5 may have a substantially elliptical shape, a substantially rectangular shape, a substantially polygonal shape, or the like in a top view.

The light-transmissive member 5 includes at least one of a resin material such as a polycarbonate resin, an acrylic resin, a silicone resin, or an epoxy resin, or a glass material, which have light transmissivity with respect to light emitted from each of the first light source 1 and the second light source 2. The light transmissivity of the light-transmissive member 5 preferably refers to having a light transmittance of 60% or more with respect to the emission peak wavelength of the light emitted from each of the first light source 1 and the second light source 2.

In the example illustrated in FIG. 1 to FIG. 3, the upper portion 51 is disposed above the first light source 1, the second light source 2, the first lens 3, and the second lens 4. A shape having light diffusibility or a shape that refracts light, such as an uneven shape or a Fresnel shape, may be formed in a lower surface 510 of the upper portion 51 facing the first lens 3. By forming a shape having light diffusibility or the like in the lower surface 510, the inside of the light-emitting module 100 is less likely to be visually recognized from the outside of the light-emitting module 100. Accordingly, the aesthetic appearance of the light-emitting module 100 can be improved. From the viewpoint of facilitating the light distribution control of light emitted from the light-emitting module 100, a shape formed in the lower surface 510 is preferably a shape having only a function to diffuse or scatter light without having a light control function by refraction or diffraction.

The cylindrical portion 52 is a portion having a cylindrical shape and supporting the upper portion 51. The leg portion 53 is a portion located outward of the cylindrical portion 52 in a top view. The leg portion 53 can be used to fix the light-transmissive member 5 to a housing of a smartphone or the like.

### (Wiring Substrate 6)

As illustrated in FIG. 1 to FIG. 4, the light-emitting module 100 can include a wiring substrate 6. The first light source 1 and the second light source 2 are disposed on the surface on the +Z side of the wiring substrate 6. In the example illustrated in FIG. 1, the wiring substrate 6 is a plate-shaped member having a substantially circular shape in a top view. In the example illustrated in FIG. 2, the wiring substrate 6 is bonded to the first lens 3 by a second bonding member 61. The second bonding member 61 is annularly disposed at a position where the upper surface of the wiring substrate 6 faces a bottom surface 32 located on the outer edge of the first lens 3. The wiring substrate 6 includes wiring on which the first light source 1, the second light source 2, and the like can be mounted. The shape of the wiring substrate 6 in a top view may be a substantially rectangular shape, a substantially elliptical shape, a substantially polygonal shape, or the like.

As a base material of the wiring substrate 6, an insulating material is preferably used, and a material that does not easily transmit light emitted from the first light source 1 and the second light source 2, external light, and the like is preferably used. Further, a material having a certain strength is preferably used for the wiring substrate 6. Specifically, as the base material of the wiring substrate 6, a ceramic such as alumina, aluminum nitride, mullite, or silicon nitride, or a resin such as a phenol resin, an epoxy resin, a polyimide resin, a bismaleimide-triazine resin (BT resin), polyphthalamide, or a polyester resin can be used.

The wiring substrate 6 includes wiring disposed, for example, on the surface of the base material. The wiring is composed of, for example, a metal such as Cu, Ag, Au, Al, Pt, Ti, W, Pd, Fe, or Ni and/or an alloy containing one or more of these metals.

The light-emitting module 100 does not necessarily include the one wiring substrate 6, and may include a plurality of wiring substrates including, for example, a first wiring substrate and a second wiring substrate. The first light source 1 and the second light source 2 may be disposed on the respective wiring substrates. For example, the first light source 1 may be disposed on the first wiring substrate and the second light source 2 may be disposed on the second wiring substrate.

### (First Light Source 1 and Second Light Source 2)

Next, the configurations of the first light source 1 and the second light source 2 will be described in detail with reference to FIG. 3 and FIG. 5 to FIG. 7.

As illustrated in FIG. 3, the first light source 1 includes the nine light-emitting parts 10, and the light-shielding member 15 can integrally hold a plurality of light-emitting elements 12 and a plurality of wavelength conversion members 14. In the example illustrated in FIG. 3, the light-shielding member 15 integrally holds nine light-emitting elements 12 and nine wavelength conversion members 14 of the nine light-emitting parts 10.

In the example illustrated in FIG. 3, the first light source 1 includes the nine light-emitting parts 10, that is, the first light-emitting part 10-1 and the second light-emitting parts 10-2 to 10-9. The nine light-emitting parts 10 are arranged, for example, in the vertical direction or the lateral direction or in a matrix in a top view. From another viewpoint, the nine light-emitting parts 10 are arranged along the X direction, or are arranged along the Y direction orthogonal to the X direction. In the example illustrated in FIG. 3, the nine light-emitting parts 10 are arranged along the X direction and the Y direction. The quantity of the light-emitting parts 10 included in the first light source 1 does not have to be nine. As long as the first light source 1 includes first light-emitting part(s) and a plurality of second light-emitting parts arranged around the first light-emitting part(s), the quantity of the first light-emitting parts and second light-emitting parts included in the first light source 1 may be any.

The first light-emitting part 10-1 and the second light-emitting parts 10-2 to 10-9 each have the light-emitting surface 11. The respective light-emitting surfaces 11 of the first light-emitting part 10-1 and the second light-emitting parts 10-2 to 10-9 are preferably disposed inward of the first lens 3 illustrated in FIG. 2 (inward relative to the outer shape of the first lens 3) and more preferably disposed inward of the first incident surface 35 of the first lens 3 in a top view. Accordingly, light from the first light source 1 is easily incident on the first lens 3. The first light-emitting part 10-1 and the second light-emitting parts 10-2 to 10-9 overlap the respective light-emitting surfaces 11 in a top view. Thus, the reference numeral of each of the first light-emitting part 10-1 and the second light-emitting parts 10-2 to 10-9 and the reference numeral of a corresponding light-emitting surface 11 are written together in the example illustrated in FIG. 3. Further, in the following description, if two or more components substantially coincide with each other or overlap each other, reference numerals may be written together.

The length of a light-emitting surface 11 along the X direction and the length of the light-emitting surface 11 along the Y direction are each, for example, 30 μm or more and 2,000 μm or less, and preferably 100 μm or more and 1,000 μm or less. The length of the light-emitting surface 11 along the X direction and the length of the light-emitting surface 11 along the Y direction may be substantially equal to each other or may be different from each other. In the example illustrated in FIG. 3, light-emitting surfaces 11 of adjacent light-emitting parts 10 are arranged at a predetermined interval in a top view. From the viewpoint of light emission characteristics of the first light source 1, the smaller the predetermined interval, the more preferable. However, there are limits to narrow the intervals at which the plurality of light-emitting parts 10 can be mounted. To obtain both good light emission characteristics and narrow intervals at which the plurality of the light-emitting parts 10 can be mounted, the predetermined interval is preferably 10 μm or more and 50 μm or less. In the example illustrated in FIG. 3, the shape of the light-emitting surface 11 in a top view is a substantially rectangular shape. However, the shape of the light-emitting surface 11 in a top view may be a substantially circular shape or a substantially elliptical shape, or may be a polygonal shape such as a substantially triangular shape or a substantially hexagonal shape.

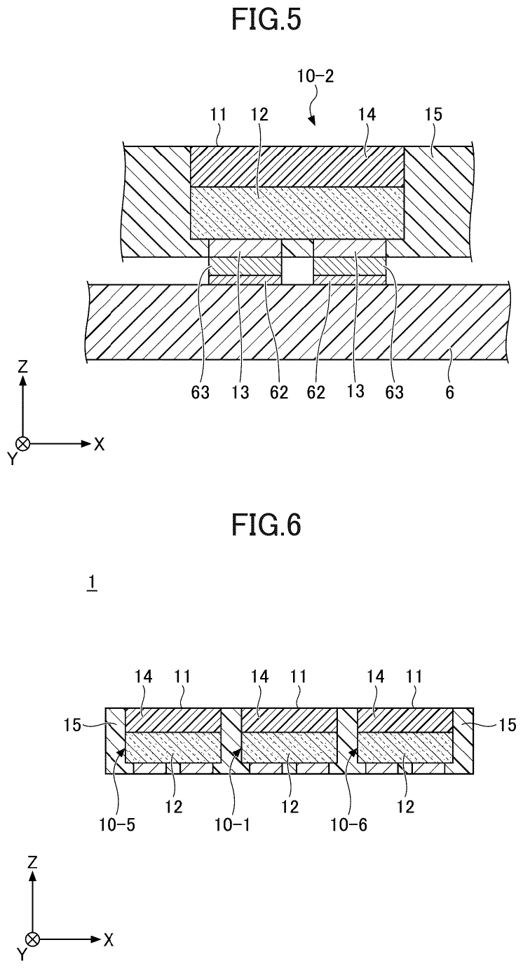

FIG. 5 is a schematic cross-sectional view taken through line V-V of FIG. 3. The main configurations of the first light-emitting part 10-1, the second light-emitting parts 10-2 to 10-9, and the third light-emitting part 20 are the same. Therefore, the description of the configuration of the second light-emitting part 10-2 illustrated in FIG. 5 can be applied to each of the first light-emitting part 10-1, the second light-emitting part 10-3 to the second light-emitting part 10-9, and the third light-emitting part 20 by appropriately replacing the names, the reference numerals, and the like of the second light-emitting part 10-2.

In the example illustrated in FIG. 5, the second light-emitting part 10-2 includes a light-emitting element 12, a wavelength conversion member 14 disposed on the light-emitting element 12, and a light-shielding member 15 covering the lateral surface(s) of the light-emitting element 12 and the lateral surface(s) of the wavelength conversion member 14. The second light-emitting part 10-2 emits light toward a region above the first light source 1 from a light-emitting surface 11. The light-emitting surface 11 refers to a main light extraction surface of the second light-emitting part 10-2. The light emitted from the second light-emitting part 10-2 may be white light or may be light having a specific wavelength such as blue light. The wavelength and chromaticity of the light emitted from the second light-emitting part 10-2 may be appropriately selected according to the intended use of the light-emitting module 100.

The light-emitting parts 10 and the third light-emitting part 20 include the light-emitting elements 12 and the wavelength conversion members 14. Thus, the light-emitting parts 10 and the third light-emitting part 20 can emit mixed color light in which the color of light emitted from the light-emitting elements 12 and the color of light emitted from the wavelength conversion members 14 are mixed. In the light-emitting parts 10, the degree of freedom in the color of light emitted from the first light source 1 can be increased by combining the light-emitting elements 12 and the wavelength conversion members 14. In addition, including the light-shielding member 15 can shield light emitted from the light-emitting elements 12 by the light-shielding member 15, thereby enabling control of the spread of light emitted from the light-emitting parts 10 and the like.

In the example illustrated in FIG. 5, the second light-emitting part 10-2 is disposed on the surface on the +Z side of the wiring substrate 6, with the upper surface of the second light-emitting part 10-2 serving as the light-emitting surface 11 and the surface opposite the light-emitting surface 11 serving as a mounting surface. The wavelength conversion member 14 is provided on the surface on the +Z side of the light-emitting element 12. The light-shielding member 15 covers the lateral surfaces of the light-emitting element 12 and the lateral surfaces of the wavelength conversion member 14 except for the upper surface of the wavelength conversion member 14.

At least a pair of positive and negative electrodes 13 are provided on the surface (that is, the lower surface) of the light-emitting element 12 opposite the light-emitting surface 11.

The light-emitting element 12 is preferably formed of various semiconductors such as group III-V compound semiconductors and group II-VI compound semiconductors. As the semiconductors, nitride-based semiconductors such as In_{X}Al_{Y}Ga_{1-X-Y}N (0≤X, 0≤Y, X+Y≤1) are preferably used, and InN, AlN, GAN, InGaN, AlGAN, InGaAlN, and the like can also be used. The light-emitting element 12 is, for example, an LED or a laser diode (LD). The emission peak wavelength of the light-emitting element 12 is preferably 400 nm or more and 530 nm or less, more preferably 420 nm or more and 490 nm or less, and even more preferably 450 nm or more and 475 nm or less, from the viewpoint of emission efficiency, excitation of a wavelength conversion substance, and the like.

The wavelength conversion member 14 is a member having, for example, a substantially rectangular shape in a top view. The wavelength conversion member 14 is disposed so as to cover the upper surface of the light-emitting element 12. The wavelength conversion member 14 contains a wavelength conversion substance that converts a wavelength of at least a portion of light from the light-emitting element 12. The wavelength conversion member 14 can be formed by using a light-transmissive resin material or an inorganic material such as a ceramic or glass. As the resin material, a thermosetting resin such as a silicone resin, a silicone-modified resin, an epoxy resin, an epoxy-modified resin, or a phenol resin can be used. In particular, a silicone resin or a modified resin thereof having high light resistance and heat resistance is preferable. As used herein, the term “light-transmissive” means that 60% or more of the light from the light-emitting element 12 is preferably transmitted. Further, a thermoplastic resin such as a polycarbonate resin, an acrylic resin, a methylpentene resin, or a polynorbornene resin can be used for the wavelength conversion member 14. For example, the wavelength conversion member 14 may be a resin material, a ceramic, glass, or the like containing a wavelength conversion substance, a sintered body of a wavelength conversion substance, or the like. Further, the wavelength conversion member 14 may contain a light diffusing substance in a resin material, a ceramic, glass, or the like. Further, the wavelength conversion member 14 may be formed of a plurality of layers including a layer that contains a wavelength conversion substance and a layer that does not contain a wavelength conversion substance. For example, the wavelength conversion member 14 may include a wavelength conversion layer that contains a wavelength conversion substance and a light diffusing layer that is located on the upper surface of the wavelength conversion layer and contains a light diffusing substance. Instead of the light diffusing layer or in addition to the light diffusing layer, the wavelength conversion member may include a light-transmissive layer that does not contain a wavelength conversion substance and a light diffusing substance.

Examples of a wavelength conversion substance contained in the wavelength conversion member 14 include yttrium aluminum garnet based phosphors (for example, (Y, Gd)₃(Al, Ga)₅O₁₂: Ce), lutetium aluminum garnet based phosphors (for example, Lu₃(Al, Ga)₅O₁₂: Ce), terbium aluminum garnet based phosphors (for example, Tb₃(Al, Ga)₅O₁₂: Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba,Sr,Ca,Mg)₂SiO₄:Eu), oxynitride based phosphors such as β-SiAlON based phosphors (for example, (Si,Al)₃(O,N)₄:Eu) and α-SiAlON based phosphors (for example, Ca(Si,Al)₁₂(O,N)₁₆:Eu), nitride based phosphors such as LSN based phosphors (for example, (La,Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ)F₆₋ₓ: Mn, where x satisfies 0<x<1), and MGF based phosphors (for example, 3.5MgO·0.5MgF₂·GeO₂:Mn), quantum dots having a Perovskite structure (for example, (Cs,FA,MA)(Pb,Sn)(F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu)(In,Ga)(S,Se)₂). The wavelength conversion substances described above are particles. One of these wavelength conversion substances may be used alone, or two or more of these wavelength conversion substances may be used in combination.

Each of the light-emitting parts 10 and the third light-emitting part 20 includes; for example, a blue light-emitting element as a light-emitting element 12, and a wavelength conversion member 14 of each of the light-emitting parts 10 and the third light-emitting part 20 contains a wavelength conversion substance that converts the wavelength of light emitted from the light-emitting element 12 into the wavelength of yellow. Accordingly, white light is emitted. As a light diffusing substance contained in the wavelength conversion member 14, titanium oxide, barium titanate, aluminum oxide, silicon oxide, or the like can be used.

The light-shielding member 15 is a member covering the lateral surface(s) of the light-emitting element 12 and the lateral surface(s) of the wavelength conversion member 14. The light-shielding member 15 directly or indirectly covers the lateral surface(s) of the light-emitting element 12 and the lateral surface(s) of the wavelength conversion member 14. The upper surface of the wavelength conversion member 14 is exposed from the light-shielding member 15 and functions as a light-emitting surface 11 of each of the light-emitting parts 10 and the third light-emitting part 20. To improve the light extraction efficiency, the light-shielding member 15 is preferably formed of a member having a high light reflectance. For example, a resin material containing a light reflective substance such as a white pigment can be used for the light-shielding member 15.

Examples of the light reflective substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. It is preferable to use one of the above substances alone or a combination of two or more of the above substances. Further, as the resin material, it is preferable to use a base material including a resin material whose main component is a thermosetting resin such as an epoxy resin, an epoxy-modified resin, a silicone resin, a silicone-modified resin, or a phenol resin. The light-shielding member 15 may be configured with a member having light absorbability with respect to visible light. If the light-shielding member 15 is configured with a member having light absorbability, the light-shielding member 15 may contains a light absorbing substance such as carbon black.

The first light source 1 is electrically connected to wiring 62 of the wiring substrate 6. The wiring substrate 6 preferably includes the wiring 62 on the surface of the wiring substrate 6. The wiring substrate 6 may include the wiring 62 inside the wiring substrate 6. The wiring substrate 6 is electrically connected to each of the light-emitting parts 10 included in the first light source 1 by connecting the wiring 62 of the wiring substrate 6 to a pair of positive and negative electrodes 13 of each of the light-emitting parts 10 via electrically-conductive members 63. The configuration, the size, and the like of the wiring 62 of the wiring substrate 6 are set according to the configuration, the size, and the like of the electrodes 13 of each of the light-emitting parts 10. The second light source 2 may be disposed on the wiring substrate 6 in addition to the first light source 1. In this case, the second light source 2 is disposed on the upper surface of the wiring substrate 6 and is positioned separated from the first light source 1 in the in-plane direction. The first light source 1 and the second light source 2 may be disposed on different wiring substrates.

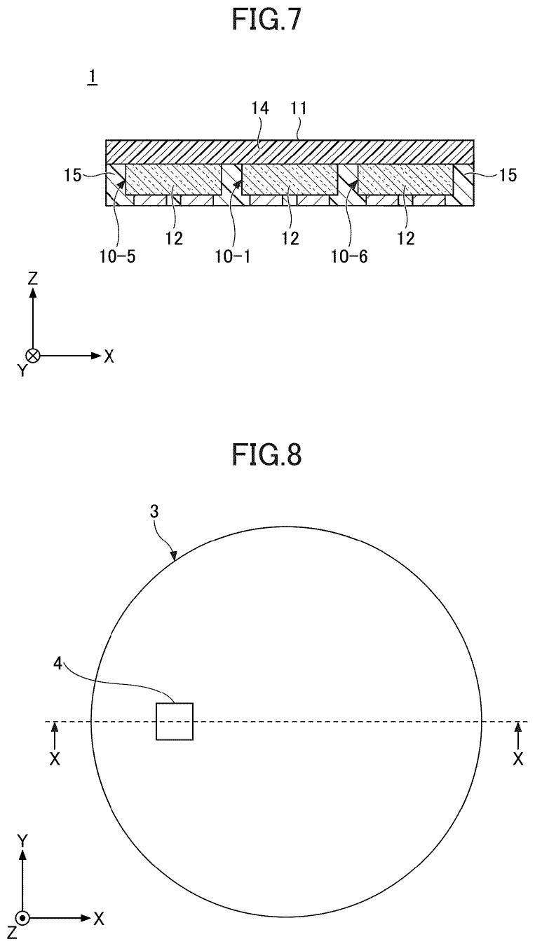

FIG. 6 is a schematic cross-sectional view illustrating a first example of the configuration of a first light source 1. FIG. 7 is a schematic cross-sectional view illustrating a second example of the configuration of a first light source 1. FIG. 6 and FIG. 7 schematically illustrate cross sections of the first light sources 1 including first light-emitting parts 10-1, second light-emitting parts 10-5, and second light-emitting parts 10-6.

In the first light source 1 according to the first example illustrated in FIG. 6, the first light-emitting part 10-1, the second light-emitting part 10-5, and the second light-emitting part 10-6 include respective wavelength conversion members 14. Light-emitting elements 12 included in the first light-emitting part 10-1, the second light-emitting part 10-5, and the second light-emitting part 10-6 are positioned separated from each other with a light-shielding member 15 interposed therebetween. Further, the wavelength conversion members 14 included in the first light-emitting part 10-1, the second light-emitting part 10-5, and the second light-emitting part 10-6 are positioned separated from each other with the light-shielding member 15 interposed therebetween.

Conversely, in the first light source 1 according to the second example illustrated in FIG. 7, the first light-emitting part 10-1, the second light-emitting part 10-5, and the second light-emitting part 10-6 include one common wavelength conversion member 14. In both the first and second examples, light-emitting elements 12 included in the first light-emitting part 10-1, the second light-emitting part 10-5, and the second light-emitting part 10-6 are positioned separated from each other with a light-shielding member 15 interposed therebetween. Conversely, in the second example, the one wavelength conversion member 14 is disposed so as to cover the light-emitting elements 12 included in the first light-emitting part 10-1, the second light-emitting part 10-5, and the second light-emitting part 10-6.

### (First Lens 3 and Second Lens 4)

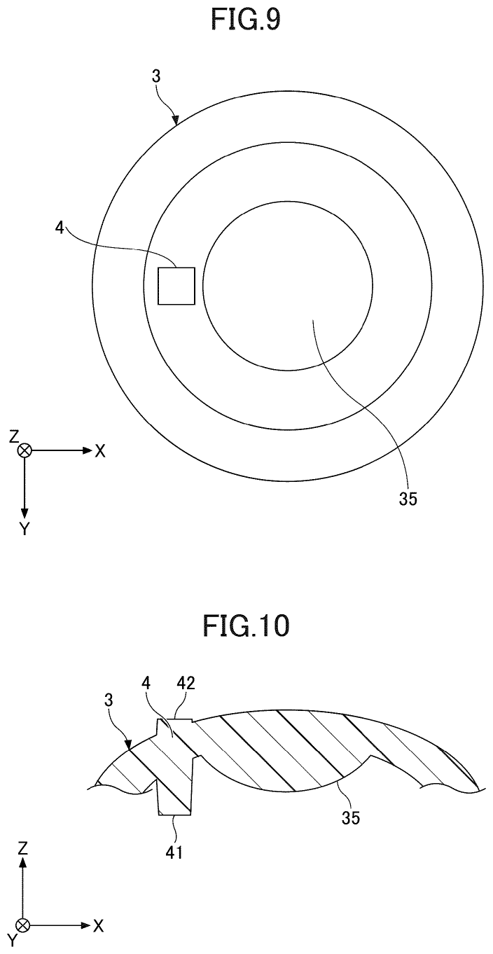

Next, the configurations of the first lens 3 and the second lens 4 will be described in detail with reference to FIG. 8 to FIG. 10. FIG. 8 is a schematic top view illustrating an example of the configuration of the first lens 3. FIG. 9 is a schematic bottom view illustrating an example of the configuration of the first lens 3. FIG. 10 is a schematic cross-sectional view taken through line X-X of FIG. 8. In FIG. 9, some lines are omitted.

In the example illustrated in FIG. 8, the shape of the outer edge of the first lens 3 in a top view is a substantially circular shape. However, the shape of the outer edge of the first lens 3 in a top view may be a substantially rectangular shape, a substantially elliptical shape, a substantially polygonal shape, or the like. Further, the shape of the outer edge of the first lens 3 in a top view may be rotationally symmetric. Considering that an imaging range of a general imaging device is substantially rectangular, it is preferable that the shape of the outer edge of the first lens 3 in a top view is four-fold rotationally symmetric or two-fold rotationally symmetric.

In the example illustrated in FIG. 9 and FIG. 10, the first lens 3 has the first exit surface 31 convex toward the side opposite to the first light source 1. The first exit surface 31 is located opposite to the first incident surface 35, that is, located on the side of the first lens 3 from which light from the first light source 1 exits. In the first lens 3, the size of the first lens 3 in a top view, the radius of curvature of the first incident surface 35, the radius of curvature of the convex surface of the first exit surface 31, the thickness of the lens, the shapes of the convex surfaces of the first incident surface 35 and the first exit surface 31, and the like can be appropriately changed.

The first lens 3 includes at least one of a resin material such as a polycarbonate resin, an acrylic resin, a silicone resin, or an epoxy resin, or a glass material, which has light transmissivity with respect to light L emitted from the first light source 1. If the first lens 3 and the second lens 4 are a monolithic member, the second lens 4 can be composed of the same material as that of the first lens 3.

In the example illustrated in FIG. 8 to FIG. 10, the first lens 3 and the second lens 4 are a monolithic member. For example, the first lens 3 and the second lens are composed of a resin material having light transmissivity, and are monolithically manufactured by injection molding or the like. The light transmissivity of the first lens 3 and the second lens 4 preferably refers to having a light transmittance of 60% or more with respect to the emission peak wavelength of the light L1 from the first light-emitting part 10-1 and the light L2 from the third light-emitting part 20. Because the first lens 3 and the second lens 4 are the monolithic member, the light-emitting module 100 can be easily assembled. If the first lens 3 and the second lens 4 are individual members, for example, the first lens 3 and the second lens 4 may be manufactured in individual molding processes. Further, if the first lens 3 and the second lens 4 are individual members, the first lens 3 and the second lens 4 may be disposed separated from each other in the in-plane direction.

### (Second Lenses 4 According to Modifications)

Second lenses 4 according to various modifications will be described below.

### (Second Lens 4 According to First Modification)

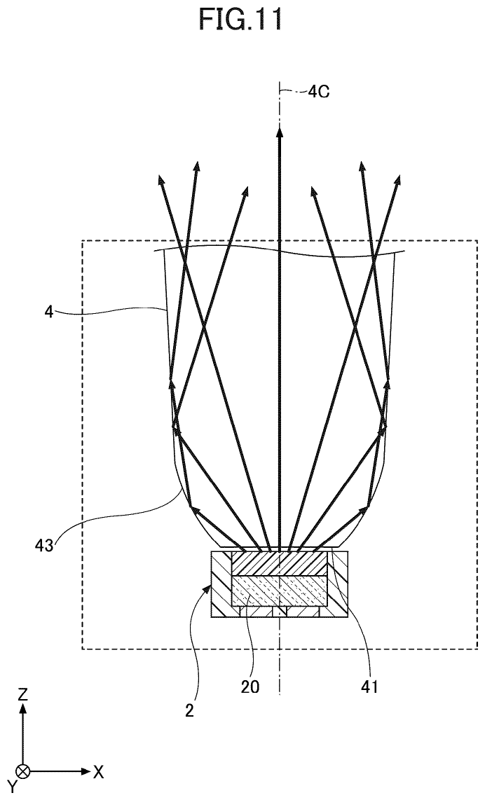

FIG. 11 is a schematic cross-sectional view illustrating a second lens 4 according to a first modification. FIG. 11 illustrates a cross section including a second optical axis 4C of the second lens 4 in the vicinity of a second incident surface 41 of the second lens 4.

The second lens 4 according to the first modification differs from the second lens 4 according to the above-described embodiment, in that the second lens 4 according to the first modification includes a total reflection portion 43 located between the second incident surface 41 and a second exit surface 42 as illustrated in FIG. 10 and configured to totally reflect light emitted from the third light-emitting part 20 and incident on the second incident surface 41. The total reflection portion 43 is located at a position lower than the lowest portion of the first incident surface 35 of the first lens 3. The inclination of the surface of the total reflection portion 43 is determined such that the total reflection portion 43 totally reflects the light emitted from the third light-emitting part 20 and incident on the second incident surface 41. In the example illustrated in FIG. 11, the total reflection portion 43 includes a curved surface. In the second lens 4 according to the first modification, the cross-sectional area orthogonal to the second optical axis 4C decreases nonlinearly toward the third light-emitting part 20.

The second lens 4 according to the first modification includes the total reflection portion 43, and thus the light emitted from the third light-emitting part 20 and incident on the second incident surface 41 does not readily leak from the lateral surfaces of the second lens 4. Accordingly, the light emitted from the third light-emitting part 20 and incident on the second incident surface 41 is less likely to leak from the lateral surfaces of the second lens 4 and is less likely to be incident on the first incident surface 35 of the first lens 3. As a result, the amount of stray light generated when the light from the third light-emitting part 20 is incident on the first lens 3 can be reduced.

Further, by adjusting the inclination angle of the total reflection portion 43, as illustrated in FIG. 4, the second irradiation region Ar2 of the light L2 from the third light-emitting part 20 can be positioned close to the first irradiation region Ar1 of the light L1 from the first light-emitting part 10-1 on the irradiation surface S irradiated with light emitted from the light-emitting module 100. Accordingly, the amount of the light L1 from the first light-emitting part 10-1 can be supplemented by the amount of the light L2 from the third light-emitting part 20, and thus, the amount of light emitted from the light-emitting module 100 can be increased in the telephoto irradiation mode.

### (Second Lens 4 According to Second Modification)

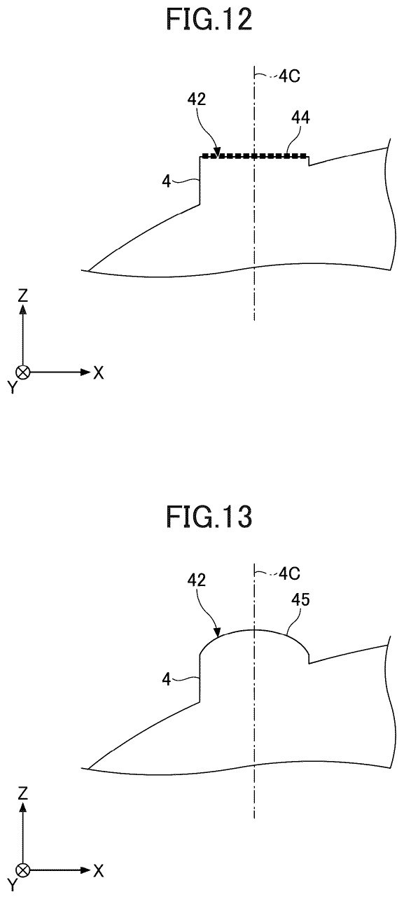

FIG. 12 is a schematic cross-sectional view illustrating a second lens 4 according to a second modification. FIG. 12 illustrates a cross section including a second optical axis 4C of the second lens 4 in the vicinity of a second exit surface 42 of the second lens 4.

As illustrated in FIG. 12, the second lens 4 according to the second modification differs from the second lens 4 according to the above-described embodiment in that the second exit surface 42 has a plurality of recesses and projections 44. The plurality of recesses and projections 44 include either a plurality of recesses or a plurality of projections, or include both a plurality of recesses and a plurality of projections. The plurality of recesses and projections 44 may have a Fresnel shape or the like.

The plurality of recesses and projections 44 included in the second exit surface 42 enable diffusion of light emitted from the second lens 4. Accordingly, illuminance unevenness of light emitted from the second lens 4 can be reduced. Further, when the second exit surface 42 has the plurality of recesses and projections 44, the inside of the light-emitting module 100 is less likely to be visually recognized through the second exit surface 42, and thus the aesthetic appearance of the light-emitting module 100 can be improved.

### (Second Lens 4 According to Third Modification)

FIG. 13 is a schematic cross-sectional view illustrating a second lens 4 according to a third modification. FIG. 13 illustrates a cross section including a second optical axis 4C of the second lens 4 in the vicinity of a second exit surface 42 of the second lens 4.

As illustrated in FIG. 13, the second lens 4 according to the third modification differs from the second lens 4 according to the above-described embodiment in that the second exit surface 42 includes a convex surface 45. The convex surface 45 is a curved surface convex toward the side opposite to the side on which the third light-emitting part 20 is located.

The second exit surface 42 including the convex surface 45 can control the distribution of light emitted from the second lens 4 by using the radius of curvature of the convex surface 45. Accordingly, the degree of freedom in controlling the distribution of light emitted from the second lens 4 can be increased. The convex surface 45 may be, for example, a plano-convex lens surface or a cylindrical lens surface. In the second lens 4 illustrated in FIG. 13, for example, light passing through the second optical axis 4C, of the light L2 emitted from the third light-emitting part 20, has the highest emission intensity.

### (Second Lens 4 According to Fourth Modification)

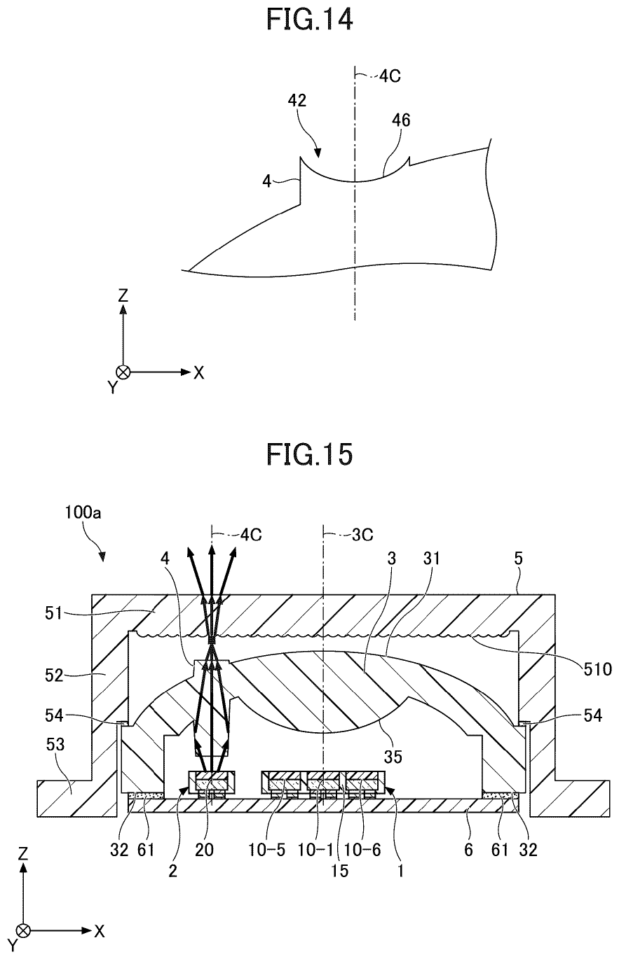

FIG. 14 is a schematic cross-sectional view illustrating a second lens 4 according to a fourth modification. FIG. 14 illustrates a cross section including a second optical axis 4C of the second lens 4 in the vicinity of a second exit surface 42 of the second lens 4.

As illustrated in FIG. 14, the second lens 4 according to the fourth modification differs from the second lens 4 according to the above-described embodiment in that the second exit surface 42 includes a concave surface 46. The concave surface 46 is a curved surface concave toward the third light-emitting part 20. The concave surface 46 is, for example, a plano-concave lens surface.

The second exit surface 42 including the concave surface 46 can control the distribution of light emitted from the second lens 4 by using the radius of curvature of the concave surface 46. Accordingly, the degree of freedom in controlling the distribution of light emitted from the second lens 4 can be increased.

### Modifications

Next, light-emitting modules according to various modifications of the embodiment will be described. The same names and reference numerals as those in the above-described embodiment denote the same or similar members or components, and a detailed description thereof will be omitted as appropriate.

### <Light-Emitting Module According to First Modification>

FIG. 15 is a schematic cross-sectional view illustrating an example of a light-emitting module 100a according to a first modification. The top view of the light-emitting module 100a is the same as that of the light-emitting module 100 illustrated in FIG. 1. FIG. 15 illustrates a cross section taken through a line corresponding to the line II-II of FIG. 1.

In the light-emitting module 100a, a first light-emitting part 10-1 includes a first phosphor layer, second light-emitting parts 10-2 to 10-9 include respective second phosphor layers, and a third light-emitting part 20 includes a third phosphor layer. A phosphor contained in the third phosphor layer is different from a phosphor contained in the first phosphor layer. The first light-emitting part 10-1 and the third light-emitting part 20 can be driven individually. The light-emitting module 100a differs from the light-emitting module 100 according to the above-described embodiment in the above-described points.

In the example illustrated in FIG. 15, the first phosphor layer is included in a wavelength conversion member 14 included in the first light-emitting part 10-1 as illustrated in FIG. 5. The second phosphor layers are included in respective wavelength conversion members 14 included in the second light-emitting parts 10-2 to 10-9. The third phosphor layer is included in a wavelength conversion member 14 included in the third light-emitting part 20. The first light-emitting part 10-1 and the second light-emitting parts 10-2 to 10-9 can emit white light by, for example, mixing light emitted from the first phosphor layer and the second phosphor layers and light emitted from light-emitting elements 12. The third light-emitting part 20 can emit amber light by, for example, mixing light emitted from the third phosphor layer and light emitted from a light-emitting element 12.

For example, in a case where an imaging device captures an image focused on a person by using the first irradiation mode of the light-emitting module, it is preferable that the color temperature of light emitted onto the person who is a subject is made close to the color temperature of ambient light. The light-emitting module 100a can emit light of a desired color temperature by adjusting the balance between a current value applied to the first light-emitting part 10-1 and a current value applied to the third light-emitting part 20, and adjusting the color of light from the first light-emitting part 10-1 and the color of light from the third light-emitting part 20. Because the light obtained by mixing the color of the light from the first light-emitting part 10-1 and the color of the light from the third light-emitting part 20 can be emitted, the color temperature of the light emitted from the light-emitting module 100a onto the person can be made close to the color temperature of the ambient light. Accordingly, the imaging device can capture an image by using natural-colored irradiation light.

### <Light-Emitting Module According to Second Modification>

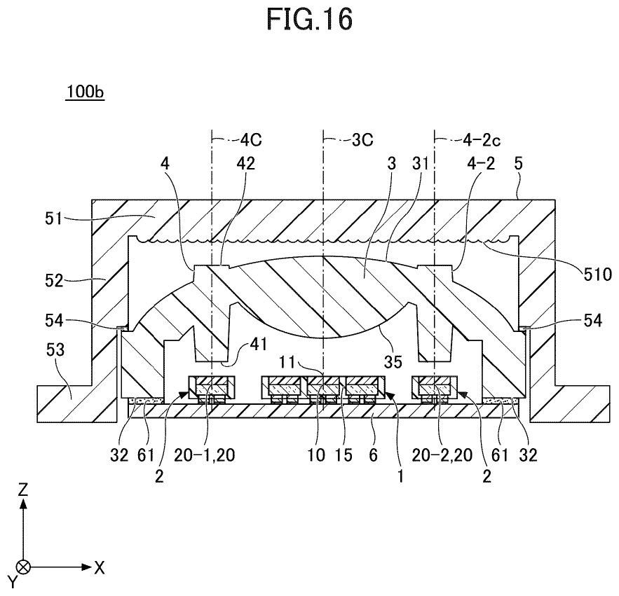

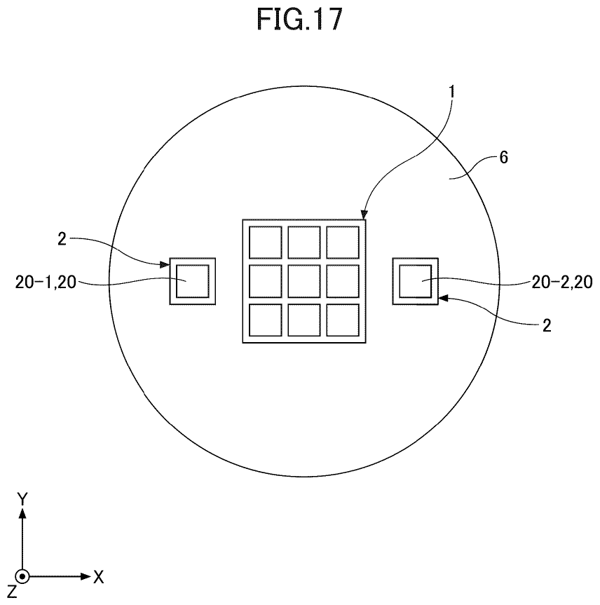

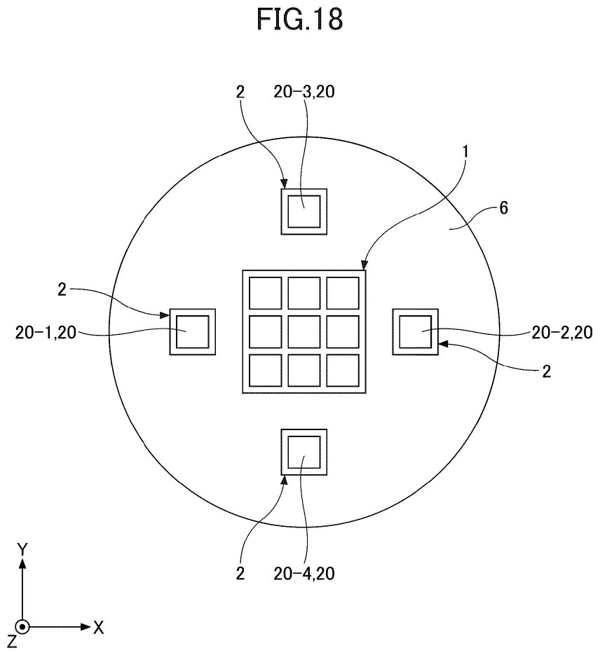

A light-emitting module according to a second modification will be described with reference to FIG. 16 to FIG. 18. FIG. 16 is a schematic cross-sectional view illustrating an example of a light-emitting module 100b according to the second modification. The top view of the light-emitting module 100b is the same as that of the light-emitting module 100 illustrated in FIG. 1 except that the light-emitting module 100b includes a third light-emitting part 20-2 and a second lens 4-2. FIG. 16 illustrates a cross section taken through a line corresponding to the line II-II of FIG. 1. FIG. 17 is a schematic top view illustrating a first example of a second light source 2 of the light-emitting module 100b. FIG. 18 is a schematic top view illustrating a second example of a second light source 2 of the light-emitting module 100b. Each of FIG. 17 and FIG. 18 illustrates the light-emitting module 100b from which the first lens 3, the second lens 4, and the light-transmissive member 5 are removed.

In the light-emitting module 100b, a second light source 2 includes a plurality of third light-emitting parts 20 arranged symmetrically with respect to the first light source 1 in a top view. The light-emitting module 100b includes at least one second lens disposed above the plurality of third light-emitting parts 20 so as to correspond to the plurality of third light-emitting parts 20. The light-emitting module 100b differs from the light-emitting module 100 according to the above-described embodiment in the above-described points.

In the example illustrated in FIG. 16 and FIG. 17, a second light source 2 includes two third light-emitting parts 20 symmetrically arranged about the first light source 1 in a top view. The two third light-emitting parts 20 include a third light-emitting part 20-1 and a third light-emitting part 20-2. The light-emitting module 100b includes a second lens 4-1 disposed above the third light-emitting part 20-1 so as to correspond to the third light-emitting part 20-1, and a second lens 4-2 disposed above the third light-emitting part 20-2 so as to correspond to the third light-emitting part 20-2. In the example illustrated in FIG. 17, in order to indicate that the third light-emitting part 20-1 and the third light-emitting part 20-2 are included in the two third light-emitting parts 20, the reference numerals of the third light-emitting part 20-1 and the third light-emitting part 20-2 are written together with the reference numerals of the third light-emitting parts 20. The second lens 4-1 and the second lens 4-2 may have the same shape or may have shapes different to each other. If the second lens 4-1 and the second lens 4-2 have shapes different to each other, for example, the second lens 4-1 has a shape corresponding to the third light-emitting part 20-1, and the second lens 4-2 has a shape corresponding to the third light-emitting part 20-2.

In the example illustrated in FIG. 18, a second light source 2 includes four third light-emitting parts 20 arranged around the first light source 1 in the top view. The four third light-emitting parts 20 include a third light-emitting part 20-1, a third light-emitting part 20-2, a third light-emitting part 20-3, and a third light-emitting part 20-4. The light-emitting module 100b can include at least one second lens 4 disposed above the four third light-emitting parts 20 so as to correspond to the four third light-emitting parts 20. In the example illustrated in FIG. 18, to indicate that the third light-emitting parts 20-1 to 20-4 are included in the four third light-emitting parts 20, the reference numerals of the third light-emitting parts 20-1 to 20-4 are written together with the reference numerals of the third light-emitting parts 20. Second lenses 4 may be the same shape or different shapes.

The second lenses 4 do not have to be disposed in one-to-one correspondence with the plurality of third light-emitting parts 20. For example, one second lens 4 having an annular shape in a top view may be disposed above the plurality of third light-emitting parts 20.

The light-emitting module 100b includes the plurality of third light-emitting parts 20 arranged symmetrically with respect to the first light source 1. Thus, on the irradiation surface S irradiated with light emitted from the light-emitting module 100b, unevenness in the illuminance distribution of light emitted from the third light-emitting parts 20 can be reduced. Further, on the irradiation surface S, a variation in the distribution of stray light of light from the first light source 1 can be easily reduced. Further, the plurality of third light-emitting parts 20 are arranged symmetrically with respect to the first light source 1 as viewed through the first lens 3. Thus, the aesthetic appearance of the light-emitting module 100b can be improved.

### <Light-Emitting Module According to Third Modification>

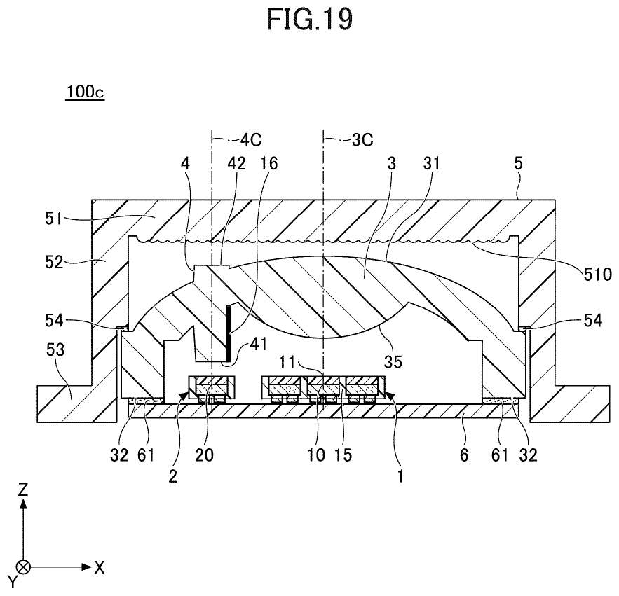

FIG. 19 is a schematic cross-sectional view illustrating an example of a light-emitting module 100c according to a third modification. The top view of the light-emitting module 100c is the same as that of the light-emitting module 100 illustrated in FIG. 1. FIG. 19 illustrates a cross section taken through a line corresponding to the line II-II of FIG. 1.

The light-emitting module 100c differs from the light-emitting module 100 according to the above-described embodiment in that a reflective film 16 is provided on lateral surface(s) of the second lens 4. A metal film or the like can be used as the reflective film 16.

In the light-emitting module 100c, light emitted from the third light-emitting part 20 and guided through the inside of the second lens 4 is reflected by the reflective film 16. Thus, leakage of light guided through the inside of the second lens 4 toward the first lens 3 can be suppressed. Accordingly, the amount of stray light generated when light guided through the inside of the second lens 4 leaks from the second lens 4 and is incident on the first incident surface 35 of the first lens 3 can be reduced. Further, light that is not incident on the first incident surface 35 of the first lens 3, of light emitted from the first light source 1, is reflected by the reflective film 16, and thus the amount of irradiation light of the first light source 1 on the irradiation surface S can be easily increased. The reflective film 16 may be provided on the entirety of the lateral surfaces of the second lens 4, or may be provided only on a lateral surface on the first lens 3 side of the second lens 4.

Although embodiments have been described in detail above, the above-described embodiments are non-limiting examples, and various modifications and substitutions can be made to the above-described embodiments without departing from the scope described in the claims.

The numbers such as ordinal numbers and quantities used in the description of the embodiments are all exemplified to specifically describe the technique of the present disclosure, and the present disclosure is not limited to the exemplified numbers. In addition, the connection relationship between the components is illustrated for specifically describing the technique of the present disclosure, and the connection relationship for implementing the functions of the present invention is not limited thereto.

The light-emitting modules according to embodiments of the present disclosure can increase the amount of light on an irradiation surface while reducing the possibility that the temperature of a light-emitting part may exceed an allowable value of a junction temperature at the time of light emission. Therefore, the light-emitting modules according to the present disclosure can be suitably used for lighting, camera flashes, vehicle headlights, and the like. However, the application of the light-emitting modules according to the present invention is not limited to the above applications.

According to one embodiment of the present disclosure, a light-emitting module that can emit light having desired characteristics can be provided.

What is claimed is:

1. A light-emitting module comprising:
a first light source; and
a second light source disposed separated from the first light source in a top view; wherein:
the first light source comprises:
a plurality of light-emitting parts including a first light-emitting part and a plurality of second light-emitting parts arranged around the first light-emitting part, and
a light-shielding member disposed between the plurality of light-emitting parts such that light-emitting surfaces of the plurality of respective light-emitting parts are exposed from the light-shielding member;
the second light source comprises a third light-emitting part electrically connected in parallel with the first light-emitting part; and
light emitted from the first light-emitting part and light emitted from the third light-emitting part at least partially overlap each other on an irradiation surface.

2. The light-emitting module according to claim 1, further comprising:
a first lens disposed above the first light source; wherein:
the first lens has a first incident surface that is convex toward the first light source and is a surface on which light from the first light source is to be incident;
the first lens has a first exit surface from which the light from the first light source exits; and
the first incident surface overlaps the first light source and does not overlap the second light source in a top view.

3. The light-emitting module according to claim 2, further comprising:
a second lens; wherein:
the second lens is disposed above the third light-emitting part; the second lens has a second incident surface that faces a light-emitting surface of the third light-emitting part; and
the second incident surface is separated from the first incident surface in the top view.

4. The light-emitting module according to claim 3, wherein:
the first lens has a first optical axis that passes through a center of the first incident surface and intersects the first light-emitting part;
the second lens has a second optical axis that passes through a center of the second incident surface and intersects the third light-emitting part; and
the second optical axis is parallel to the first optical axis.

5. The light-emitting module according to claim 3, wherein:
the second lens has a second exit surface from which the light emitted from the third light-emitting part and incident on the second incident surface exits; and
the second incident surface and the second exit surface are flat surfaces parallel to each other.

6. The light-emitting module according to claim 5, wherein the second incident surface is located at a position lower than the first incident surface, and the second exit surface is located at a position higher than the first incident surface.

7. The light-emitting module according to claim 6, wherein:
the second lens comprises a total reflection portion located between the second incident surface and the second exit surface; and
the second lens is configured to totally reflect the light emitted from the third light-emitting part and incident on the second incident surface.

8. The light-emitting module according to claim 3, wherein the first lens and the second lens are a monolithic member.

9. The light-emitting module according to claim 3, wherein:
the second light source comprises a plurality of the third light-emitting parts arranged symmetrically with respect to the first light source in the top view; and
the light-emitting module comprises one or more of the second lenses disposed above the plurality of third light-emitting parts so as to correspond to the plurality of third light-emitting parts.

10. The light-emitting module according to claim 1, wherein the light-emitting module is configured such that a current value applied to the third light-emitting part is equal to or less than a current value applied to the first light-emitting part.

11. The light-emitting module according to claim 1, wherein:
the light-emitting module is switchable between a first irradiation mode and a second irradiation mode;
in the first irradiation mode, the first light-emitting part and the third light-emitting part emit light and;
in the second irradiation mode, each of the first light-emitting part, the plurality of second light-emitting parts, and the third light-emitting part emits light; and
a light distribution angle of the light-emitting module in the first irradiation mode is smaller than a light distribution angle of the light-emitting module in the second irradiation mode.

12. A flash comprising the light-emitting module according to claim 1.

13. A light-emitting module comprising:
a first light source comprising a first light-emitting part and a plurality of second light-emitting parts arranged around the first light-emitting part; and
a second light source disposed separated from the first light source in a top view and comprising a third light-emitting part; wherein:
light from the first light-emitting part and light from the third light-emitting part at least partially overlap each other on an irradiation surface;
the light-emitting module is switchable between a first irradiation mode and a second irradiation mode,
in the first irradiation mode, the first light-emitting part and the third light-emitting part emit light and;
in the second irradiation mode, each of the first light-emitting part, the plurality of second light-emitting parts, and the third light-emitting part emits light; and
a light distribution angle in the first irradiation mode is smaller than a light distribution angle in the second irradiation mode.

14. The light-emitting module according to claim 13, further comprising:
a first lens disposed above the first light source; wherein:
the first lens has a first incident surface that is convex toward the first light source and is a surface on which light from the first light source is to be incident;
the first lens has a first exit surface from which the light from the first light source exits; and
the first incident surface overlaps the first light source and does not overlap the second light source in a top view.

15. The light-emitting module according to claim 14, further comprising:
a second lens disposed above the third light-emitting part and having a second incident surface that faces a light-emitting surface of the third light-emitting part and is positioned separated from the first incident surface in the top view.

16. The light-emitting module according to claim 15, wherein:
a first optical axis of the first lens passing through a center of the first incident surface intersects the first light-emitting part;
a second optical axis of the second lens passing through a center of the second incident surface and parallel to the first optical axis intersects the third light-emitting part.

17. The light-emitting module according to claim 15, the first lens and the second lens are parts of a monolithic member.

18. The light-emitting module according to claim 13, wherein:
the first light-emitting part comprises a first phosphor layer;
the plurality of second light-emitting parts comprises one or more second phosphor layers;
the third light-emitting part comprises a third phosphor layer;
a phosphor contained in the third phosphor layer is different from a phosphor contained in the first phosphor layer; and
the first light-emitting part and the third light-emitting part are configured to be individually driven.
